(19) United States
(12) Patent Application Publication
(10) Pub. No.: US 2012/0164791 A1
(43) Pub. Date: Jun. 28, 2012

(54) Substrate for semiconductor package and method for manufacturing the same

(75) Inventors: Dong Jin Kim, Busan (KR); Keumhee Oh, Gyeongsangnam-do (KR); Jeongwoo Ha, Gyeongsangnam-do (KR)

(73) Assignee: SAMSUNG ELECTRO-MECHANICS CO., LTD., Suwon (KR)

(21) Appl. No.: 13/373,292

(22) Filed: Nov. 10, 2011

(30) Foreign Application Priority Data
Dec. 27, 2010 (KR) 10-2010-0135628

(51) Int. Cl. H01L 21/50; B32B 27/38; B32B 3/00; B32B 9/04

(52) U.S. Cl. 438/118; 428/411.1; 428/413; 428/336; 257/E21.499

(57) ABSTRACT

Disclosed herein are a substrate for a semiconductor package and a method for manufacturing the same. The substrate for the semiconductor package includes: a semiconductor chip forming region; and a hydrophobic film for controlling the flow of an adhesive for bonding a semiconductor chip in a portion of a solder resist layer. According to the present invention, a molecular film type of chemically treated hydrophobic film is formed to effectively control the flow of epoxy resin as an adhesive for bonding a semiconductor chip at a location where the epoxy resin meets the hydrophobic film. Also, a part to be controlled is bonded to a substrate through chemical bonding, thereby maintaining a very stable form.

### CROSS REFERENCE(S) TO RELATED APPLICATIONS

This application claims the benefit under 35 U.S.C. Section 119 of Korean Patent Application Serial No. 10-2010-0135628, entitled “Substrate for Semiconductor Package and Method for Manufacturing the Same” filed on Dec. 27, 2010, which is hereby incorporated by reference in its entirety into this application.

### BACKGROUND OF THE INVENTION

1. Technical Field

The present invention relates to a substrate for a semiconductor package and a method for manufacturing the same, and more particular, to a substrate for a semiconductor package capable of effectively controlling the flow of epoxy resin, and a method for manufacturing the same.

2. Description of the Related Art

In general, in a flip-chip ball grid array (FCBGA), a semiconductor package product is completed by forming a substrate through build-up type deposition, and forming solder balls on the uppermost layer of the substrate to electrically connect a flip-chip and the substrate.

This semiconductor package product gradually requires smallness and high density due to the miniaturization of a device in which the semiconductor package product is mounted.

The importance between a substrate and a semiconductor chip has always been emphasized in an FCBGA substrate, and technique development with regard to this is being conducted at a very high speed. The direct connection between the substrate and the chip through solder, which is one of the flip chip techniques, is a solution to high input/output (I/O) due to development of semiconductor techniques, and this leads to development in an integration of semiconductor.

FIG. 1 shows a procedure for bonding a semiconductor chip and a substrate using solder. Generally, as bumps of a substrate 11 and a semiconductor chip 12 are connected to each other through solder 13, an empty space 14 is formed between the substrate 11 and the semiconductor chip 12. This empty space 14 is filled with epoxy resin 15, and thereby performs a role of protecting the connection between the semiconductor chip 12 and the substrate 11 from physical/chemical impact. Generally, in an FCB, a semiconductor chip is mounted on a center portion referred as a C4 area, and passive elements such as capacitors and resisters are mounted around the semiconductor chip in an SMD form.

Formerly, a substrate was still larger than a semiconductor chip. Therefore, the mounting of the semiconductor chip had little effect on the mounting of peripheral passive elements. However, the distance between the semiconductor chip and the passive elements is decreased on the substrate due to high integration of the semiconductor chip and the substrate. Consequently, a semiconductor mounting process may affect the protecting and mounting of the passive elements. Especially, when the flow of epoxy resin is not controlled during an injecting process of the epoxy resin, the epoxy resin flows into the passive elements and thereby affects several parts such as mounting of the passive elements and so on.

In order to solve this problem in the related art, the flow of the epoxy resin was controlled by forming a dam-type structure as shown in FIG. 2 or forming a trench-type valley on a solder resist (SR) portion located in the outer peripheral portion of the substrate as shown in FIG. 3. However, the following problems of manufacture and management arise when theses structures are formed.

More specifically, in a case where a dam structure 26 is used as shown in FIG. 2, an empty space 24 between a substrate 21 and a semiconductor chip 22 is treated with epoxy resin 25 when the substrate 21 and the semiconductor chip 22 are connected to each other by using solder 23. Herein, the height and width of the dam structure 26, which is formed on the substrate 21 for controlling the flow of the epoxy resin 25, should be controlled according to the semiconductor mounting process. Also, the dam structure may get damaged or collapse due to the height of the dam during the semiconductor mounting process, and thereby fails to work well.

In addition, if a trench-type valley 36 is formed as shown in FIG. 3, an empty space 34 between a substrate 31 and a semiconductor chip 32 is treated with epoxy resin 35 when the substrate 31 and the semiconductor chip 32 are connected to each other by using solder 33. Herein, in the trench-type valley 36 formed on a solder resister (SR) portion in the outer peripheral portion of the substrate 31 in order to control the flow of the epoxy resin 35, a step difference of solder resist (SR) between a portion with solder resist (SR) and a portion without solder resist (SR) may be generated, which causes defects during a semiconductor mounting process. In other words, the defects caused by the step difference in a thickness of solder resist are more likely to arise in the exposed portion of the substrate.

Accordingly, a certain form for controlling the flow of the epoxy resin while not having much effect on the structure of the substrate is needed. In other words, it is needed that a structure having a size of several microns or nanometers is formed to control the flow of the epoxy resin effectively, and this form of structure really needs to be developed.

### SUMMARY OF THE INVENTION

An object of the present invention is to provide a substrate for a semiconductor package capable of effectively controlling the flow of epoxy resin used for bonding a semiconductor chip in a semiconductor packaging process.

Another object of the present invention is to provide a method for manufacturing the substrate for the semiconductor package.

According to an exemplary embodiment of the present invention, there is provided a substrate for a semiconductor package, including: a semiconductor chip forming region; and a hydrophobic film for controlling the flow of an adhesive for bonding a semiconductor chip in a portion of a solder resist layer.

The hydrophobic film may be formed of a material in which one side includes hydrophobic substituent and the other side includes substituent capable of being chemically bonded with the adhesive for bonding the semiconductor chip.

The hydrophobic substituent in the material for forming the hydrophobic film may be one or more halogen atoms selected from a group consisting of fluorine, bromine, and chlorine; or one or more selected from alkyl groups.

The substituent capable of being chemically bonded with the adhesive for bonding the semiconductor chip in the material for forming the hydrophobic film may be one or more selected from a group consisting of silanol, tin (Sn)-containing compound, and carboxyl group.

The adhesive for bonding the semiconductor chip may be epoxy resin.

The hydrophobic film may be formed to have a thickness within 1 μm.

The hydrophobic film may be formed on the opposite surface of a side into which the adhesive for bonding the semiconductor chip is injected.

The hydrophobic film may be formed from a location at which the injection of the adhesive for bonding the semiconductor chip ends.

According to another exemplary embodiment of the present invention, there is provided a method for manufacturing a substrate for semiconductor packaging, including: forming a semiconductor chip on a substrate and connecting the semiconductor chip to the substrate; forming a solder resist layer on the substrate; and forming a hydrophobic film for controlling the flow of an adhesive for bonding the semiconductor chip in a portion of the solder resist layer.

The hydrophobic film may be formed by one or more methods selected from a group consisting of screen printing, stamping, and ink-jetting.

The hydrophobic film may be formed on the opposite surface of a side into which the adhesive for bonding the semiconductor chip is injected.

### BRIEF DESCRIPTION OF THE DRAWINGS

FIG. 1 is a view showing a bonding procedure between a semiconductor chip and a substrate using solder;

FIG. 2 is a view showing a case in which a dam-type structure is formed to control the flow of epoxy resin, according to the related art;

FIG. 3 is a view showing a case in which a trench-type valley is formed on a solder resist (SR) part in the outer peripheral portion of the substrate to control the flow of epoxy resin; and

FIG. 4 is a view showing a case in which the flow of epoxy resin including a hydrophobic film is controlled, according to an exemplary embodiment of the present invention.

FIG. 5 is a view showing a case in which the flow of epoxy resin including a hydrophobic film is controlled, according to another exemplary embodiment of the present invention.

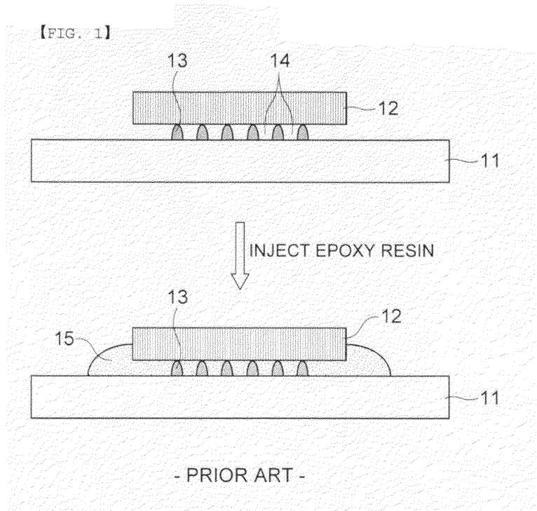

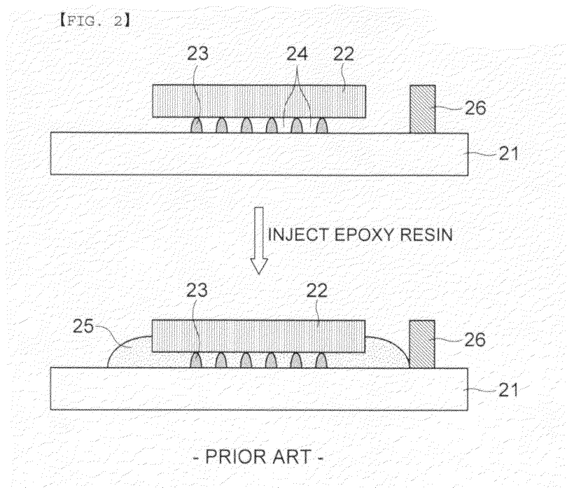

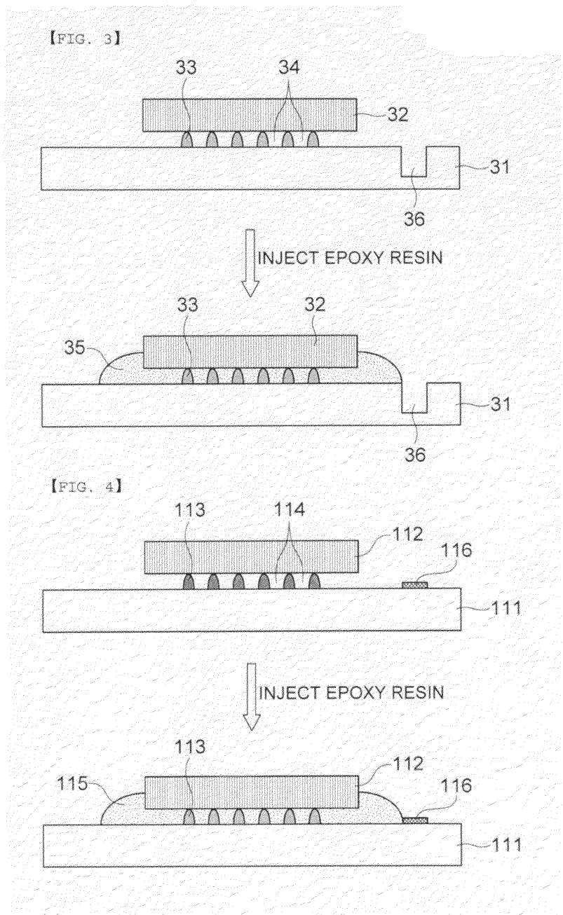

### DESCRIPTION OF THE PREFERRED EMBODIMENTS

Hereinafter, preferred embodiments will be described in detail with reference to the accompanying drawings so that they can be easily practiced by those skilled in the art to which the present invention pertains.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

In the following drawings, thicknesses or sizes of respective layers are exaggerated for convenience and clarity of description. Like numbers refer to like elements throughout the description of the figures. As used herein, the term “and/or” includes any and all combinations of one or more of the associated listed items.

The present invention relates to a substrate for a semiconductor package and a method for manufacturing the same, the substrate including a hydrophobic film in a solder resist layer so as to control the flow of epoxy resin as an adhesive used for bonding a semiconductor chip in a semiconductor packaging process.

A substrate for a semiconductor package according to an embodiment of the present invention includes a semiconductor chip forming region. The substrate and the semiconductor chip are connected by solder balls. A solder resist layer is coated on a surface of the substrate to cover a wiring circuit, in order to prevent the unintended connection due to soldering performed when component parts are mounted. The present invention includes a hydrophobic film for controlling the flow of an adhesive for bonding the semiconductor chip formed in a portion of the solder resist layer.

The hydrophobic film according to the present invention is formed to effectively control the flow of epoxy resin mainly used as the adhesive for bonding the semiconductor chip. The hydrophobic film is for preventing the epoxy resin from expanding beyond the semiconductor chip forming region and flowing to a portion of the substrate in which passive elements are located.

The epoxy resin used as the adhesive is thermosetting polymer having two or more ethyleneoxide groups in a molecule. The epoxy resin has excellent mechanical strength and transparency, which can be widely used as the adhesive for semiconductor packaging.

In the present invention, a method is developed such that the flow of the epoxy resin can be controlled by using the characteristic in which the epoxy resin expresses hydrophilicity. More particularly, the hydrophobic film is formed on the opposite surface of a side into which the epoxy resin is injected. In this case, the epoxy resin injected for bonding during a packaging process flows to some degree. When the epoxy resin meets a portion of the hydrophobic film, the flow of the epoxy resin proceeds to some degree but can be effectively controlled.

In the present invention, a material in which one side includes hydrophobic substituent and the other side includes substituent capable of being chemically bonded with the adhesive for bonding the semiconductor chip is used in order to form the hydrophobic film.

Accordingly, the side including the hydrophobic substituent controls the flow of the epoxy resin, while at the same time the side including the substituent capable of being chemically bonded is chemically bonded with the epoxy resin.

The hydrophobic film according to the present invention controls the flow of the epoxy resin by chemical bonding with the epoxy resin. Therefore, the hydrophobic film can be located more stably compared with a physical structure such a dam structure or a trench structure of the related art.

In other words, the epoxy resin is a material having hydrophilicity. Accordingly, the flow of the epoxy resin can be simply controlled when hydrophilicity/hydrophobilicity on a surface of the substrate is controlled. As such, a method of imparting the hydrophobilicity to a portion of the substrate is easier than a method of forming a relatively large structure such as a dam. This method can be expected to have no effect on characteristics of the substrate and a semiconductor mounting process.

In the material for forming the hydrophobic film, the hydrophobic substituent may be one or more halogen atoms selected from a group consisting of fluorine, bromine, and chlorine; or one or more selected from alkyl groups. The number of carbons in the alkyl groups is not specially limited, and all the alkyl groups may be used.

The substituent imparting the hydrophobilicity may be two types. One of the two types is substituting hydrogen with halogen and the other of the two types is substituting alkyl group with halogen compound.

In the material for forming the hydrophobic film, the substituent capable of being chemically bonded with the adhesive for bonding the semiconductor chip may be one or more selected from a group consisting of silanol, tin (Sn)-containing compound, and carboxyl group.

The above substituents for forming the hydrophobic film have characteristics of being chemically bonded with solder resist. In other words, the substituent for forming the hydrophobic film reacts with hydroxyl (OH) group of the solder resist to form the hydrophobic film. Accordingly, the present invention is capable of forming the hydrophobic film in a more stable structure than the physical method.

According to the present embodiment, the hydrophobic film may be formed to have a thickness within 1 μm. When the thickness of the hydrophobic film exceeds 1 μm, the problems may arise that a portion or the entire portion of the hydrophobic film is damaged by actual equipments during mounting of the semiconductor chip.

Also, the adhesive used in the present invention may be epoxy resin, but is not limited thereto.

A method for manufacturing a substrate for a semiconductor package according to the present invention will be described in detail as follows.

The method according to the present invention may include: forming a semiconductor chip on a substrate and connecting the semiconductor chip to the substrate by solder balls; forming a solder resist layer on the substrate; and forming a hydrophobic film for controlling the flow of an adhesive for bonding the semiconductor chip in a portion of the solder resist layer.

The hydrophobic film according to the present invention may be formed by one or more methods selected from a group consisting of screen printing, stamping and ink-jetting. These methods are used in the existing process and the hydrophobic film is formed by these methods without separate additive processes. Consequently, the manufacturing process according to the present invention is relatively simplified compared with the related art. Also, only desired portions can be selectively treated by these methods.

Further, the hydrophobic film according to the present invention may be formed on the opposite surface of a side into which the adhesive for bonding the semiconductor chip is injected. Accordingly, when the epoxy resin as the adhesive is injected, the flow of the epoxy resin proceeds, and stops at an area in which the hydrophobic film is located, by the hydrophobic substituent. Surely, some of the epoxy resin may flow from a position at which the epoxy resin meets the hydrophobic film to an area in which the hydrophobic film is located, but the flow of the epoxy resin is not maintained to a position at which the area of the hydrophobic film ends.

Generally, the area in which the epoxy resin is located is previously determined, and varied according to the uses of the epoxy resin. Accordingly, the hydrophobic film according to the present invention may be controlled to form from an area in which the epoxy resin is located to a position at which the flow of the epoxy resin is controlled.

Hereinafter, the present invention will be described in more detail according to exemplary embodiments of the present invention. The exemplary embodiments of the present invention are provided for describing the present invention more completely to those skilled in the art to which the present invention pertains. The following embodiments may be changed to various different forms, and the range of the present invention is not limited to the following embodiments. These embodiments make the disclosure set for herein more substantial and complete, and are provided for conveying the spirits of the present invention to those skilled in the art.

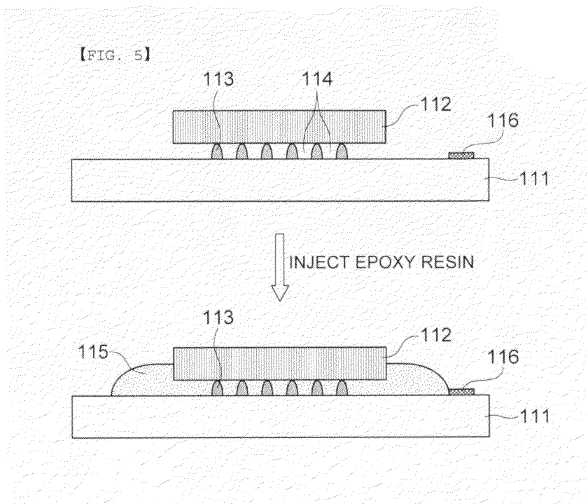

FIG. 4 is a view showing a manufacturing procedure of a substrate for a semiconductor package according to an exemplary embodiment of the present invention, and the present invention will be described, with reference to the figure.

First, a semiconductor chip 112 is formed on a substrate 111. The substrate 111 and the semiconductor chip 112 may be connected by a plurality of solder balls 113. Also, a solder resist layer may be formed on the substrate 111 for insulation of a wiring circuit. A hydrophobic film 116 for controlling the flow of an adhesive for bonding the semiconductor chip may be formed in a portion of the solder resist layer.

The forming of the hydrophobic film 116 may be performed by using one method selected from a group consisting of ink-jetting, screen printing, and stamping. The screen printing method among them may be the most preferable, but the present invention is not limited thereto.

Epoxy resin 115 as an adhesive for bonding the semiconductor chip is applied onto a substrate 111 on which the hydrophobic film 116 is formed. In this case, the epoxy resin 115 meets a portion of the hydrophobic film 116 formed on the opposite side of the injection position of the epoxy resin. Consequently, the flow of the epoxy resin can be controlled.

When an area in which the epoxy resin 15 is located is determined, the location is selected on the right side or the left side with respect to the longitudinal direction of the substrate 111 and then the hydrophobic film 116 can be chemically fixed in only the necessary area.

For example, the area in which the epoxy resin 115 is located is extended farther toward the right in FIG. 5 than in FIG. 4. In this case, the location at which the hydrophobic film 116 according to the present invention is formed may be set to move farther toward the right by the area in which the epoxy resin 115 is located.

Therefore, when the hydrophobic film is used like the present invention, the flow of the epoxy resin can be controlled by a simple method, without needing to consider problems such as limitations or immobility in using the fixed physical structure like the related art.

In addition, even though the hydrophobic film 116 according to the present invention is formed to have a thickness not exceeding 1 μm, the flow of the epoxy resin 115 can be controlled effectively. Accordingly, the problems can be effectively solved that there was a limit in controlling the flow of the epoxy resin according to thickness, height, or size of a separate structure.

According to the present invention, any limitation due to the height of a structure in forming a separate structure, that is, any height problem of equipment during a semiconductor mounting process does not exist. This is why the flow of epoxy resin as an adhesive for bonding a semiconductor chip is blocked at a location where the epoxy resin meets a molecular film type of chemically treated hydrophobic film. Therefore, by the benefit of the hydrophobic film for controlling the flow of the epoxy resin according to the present invention, the number of processes can be reduced in comparison with a separate structure according to the related art. In addition, the hydrophobic film can be controlled to have desired size and width.

Further, the existing equipment (such as, screen printing, or the like) is applicable. A part to be controlled is bonded to a substrate through chemical bonding, thereby maintaining a very stable form.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. A substrate for a semiconductor package, the substrate comprising:
a semiconductor chip forming region; and
a hydrophobic film for controlling the flow of an adhesive for bonding a semiconductor chip in a portion of a solder resist layer.

2. The substrate according to claim 1, wherein the hydrophobic film is formed of a material in which one side includes hydrophobic substituent and the other side includes substituent capable of being chemically bonded with the adhesive for bonding the semiconductor chip.

3. The substrate according to claim 2, wherein the hydrophobic substituent in the material for forming the hydrophobic film is one or more halogen atoms selected from a group consisting of fluorine, bromine, and chlorine; or one or more selected from alkyl groups.

4. The substrate according to claim 2, wherein the substituent capable of being chemically bonded with the adhesive for bonding the semiconductor chip in the material for forming the hydrophobic film is one or more selected from a group consisting of silanol, tin (Sn)-containing compound, and carboxyl group.

5. The substrate according to claim 2, wherein the adhesive for bonding the semiconductor chip is epoxy resin.

6. The substrate according to claim 1, wherein the hydrophobic film is formed to have a thickness within lgm.

7. The substrate according to claim 1, wherein the hydrophobic film is formed on the opposite surface of a side into which the adhesive for bonding the semiconductor chip is injected.

8. The substrate according to claim 1, wherein the hydrophobic film is formed from a location at which the injection of the adhesive for bonding the semiconductor chip ends.

9. A method for manufacturing a substrate for a semiconductor package, the method comprising:
forming a semiconductor chip on a substrate and connecting the semiconductor chip to the substrate;
forming a solder resist layer on the substrate; and
forming a hydrophobic film for controlling the flow of an adhesive for bonding the semiconductor chip in a portion of the solder resist layer.

10. The method according to claim 9, wherein the hydrophobic film is formed by one or more methods selected from a group consisting of screen printing, stamping and ink-jetting.

11. The method according to claim 9, wherein the hydrophobic film is formed on the opposite surface of a side into which the adhesive for bonding the semiconductor chip is injected.
